(19) United States
(12) Patent Application Publication
(10) Pub. No.: US 2014/0190553 A1
(43) Pub. Date: Jul. 10, 2014

(54) METHOD AND APPARATUS FOR GENERATING SOLARPOWER

(71) Applicant: Christoph Karl La Due, Talent, OR (US)

(72) Inventor: Christoph Karl La Due, Talent, OR (US)

(21) Appl. No.: 13/854,271

(22) Filed: Apr. 1, 2013

Related U.S. Application Data
(60) Provisional application No. 61/751,201, filed on Jan. 10, 2013.
(60) Provisional application No. 61/756,408, filed on Jan. 24, 2013.

(51) Int. Cl. H01L 31/052

(52) U.S. Cl. CPC H01L 31/0524
USPC 136/246

(57) ABSTRACT

A light energy collection apparatus, comprising a one or more concentrating optics to transfer light energy from a source of the light energy to a target of the light energy. A substrate having a photovoltaic cell (PVC) deposited thereon is the target. The PVC is to collect the light energy to be transferred from the one or more concentrating optics. A central drive axle is coupled to the substrate and a motor is coupled to the central drive axle to rotate the central drive axle about a fixed axis to position the substrate, and thereby the PVC, near the one or more concentrating optics to collect the light energy to be transferred therefrom.

### CROSS REFERENCE TO RELATED APPLICATIONS

This application claims priority to U.S. Provisional Application No. 61/751,408 filed Jan. 24, 2013 and to U.S. Provisional Application No. 61/751,201 filed Jan. 10, 2013.

### TECHNICAL FIELD

Embodiments of the invention relate to methods and apparatus for generating solar power, and in particular relate to converting sunlight into electricity directly using photovoltaics cells, or simply, photovoltaics.

### BACKGROUND ART

Solar energy, radiant light and heat from the sun, has been harnessed using technologies such as solar heating, solar thermal electricity, and solar photovoltaics.

Solar technologies are broadly characterized as either passive solar or active solar depending on the way they capture, convert and distribute solar energy. Active solar techniques include the use of photovoltaic panels to harness the energy. The conversion efficiency of photovoltaic panels is at best, using the latest technologies, approximately 20%. What is needed is a way to improve the efficiency of photovoltaic panels.

### BRIEF DESCRIPTION OF THE DRAWINGS

Embodiments of the invention will be understood more fully from the detailed description given below and from the accompanying drawings of various embodiments of the invention, which, however, should not be taken to limit the invention to the specific embodiments, but are for explanation and understanding only.

FIG. 1 illustrates a prior art flat panel photovoltaic cell.

FIG. 2 illustrates a prior art flat panel photovoltaic cell.

FIG. 3 illustrates an embodiment of the invention.

FIG. 4 illustrates an embodiment of the invention.

FIG. 5 illustrates an embodiment of the invention.

FIG. 6 illustrates a embodiment of the invention.

FIG. 7 illustrates an embodiment of the invention.

FIG. 8 illustrates an embodiment of the invention.

FIG. 9 illustrates an embodiment of the invention.

FIG. 10 illustrates an embodiment of the invention.

### DESCRIPTION OF THE EMBODIMENTS

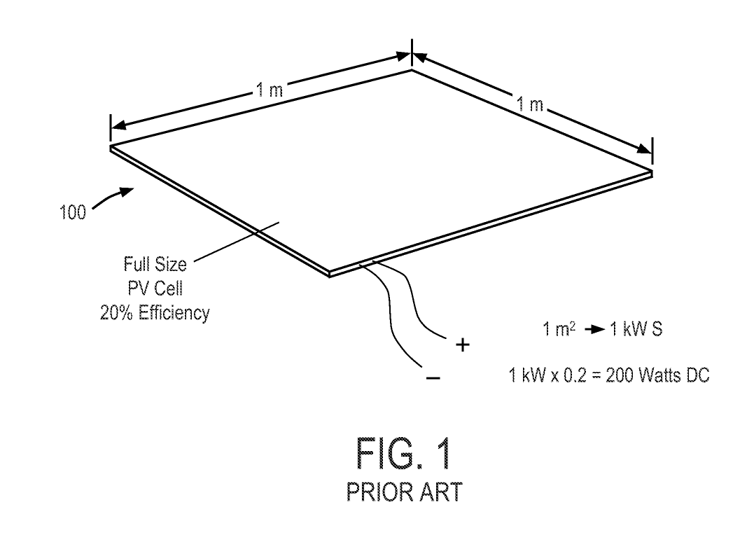

With reference to FIG. 1, one square meter of a flat panel Photovoltaic (PV) cell 100 captures approximately 1 kilowatt (KW) of light. With a prior art PV cell, or simply, PV, having 20% conversion efficiency, 200 watts of direct current (DC) energy are produced.

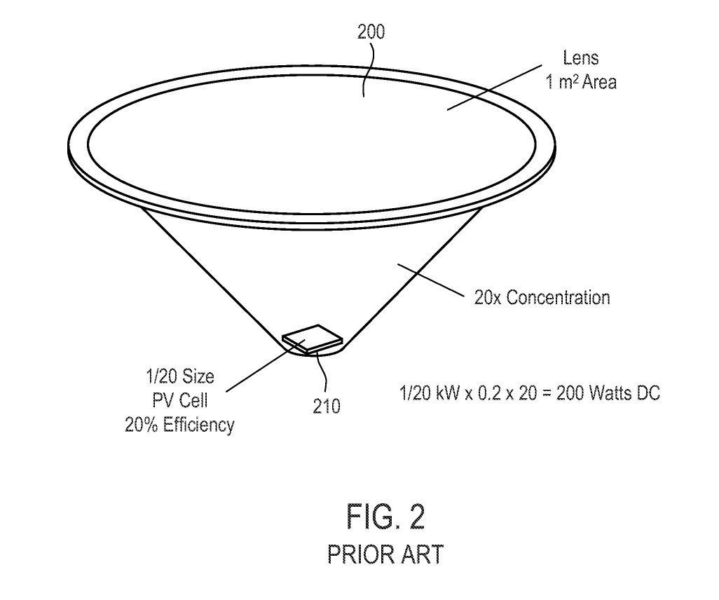

in FIG. 2, a one square meter lens 200 captures the same amount of light as the one square meter flat panel 100, which is then magnified by the lens, for example, magnified 20 times by the lens, onto a smaller amount of PV, that is, a PV with smaller surface area than the surface area of the lens. In this example, only 1/20th of a square meter of PV 210 is required to produce the same amount of electricity as the one square meter flat panel of PV 100. Since the full one square meter of light is concentrated on the smaller amount of PV 210, and the PV 210 is also 20% efficient, 200 watts of electricity are again produced. By using a concentrating lens 200, 1/20th of the PV produces the same amount of energy as 1 square meter of flat panel PV 100 illustrated in FIG. 1.

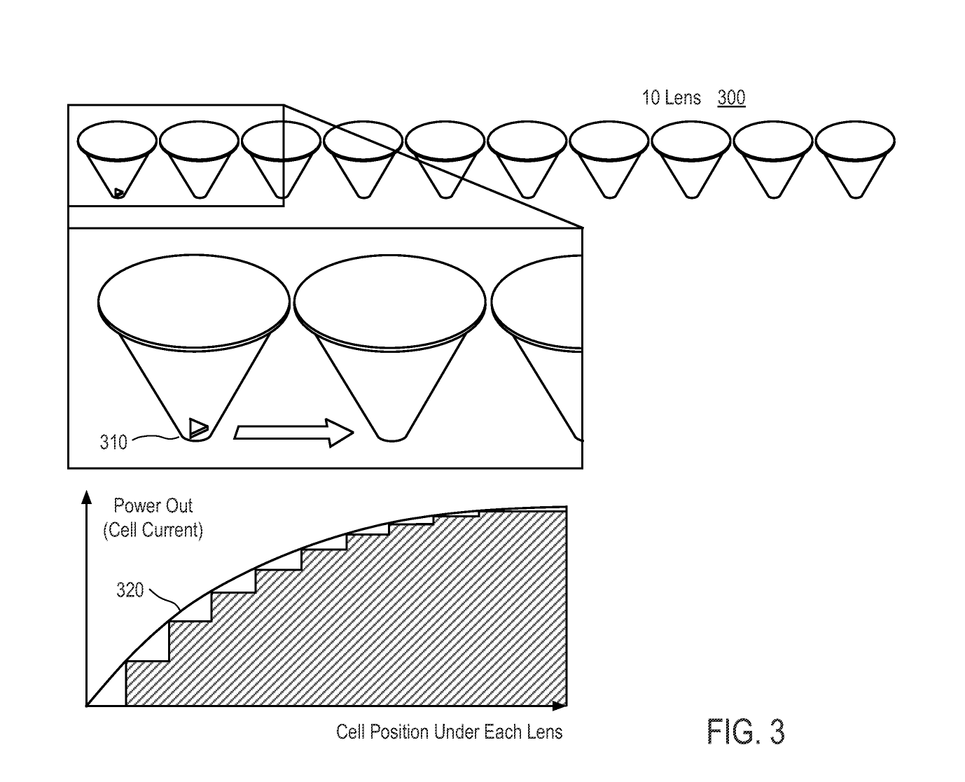

in FIG. 3, according to one embodiment of the invention, the same area of lens 200 (one square meter) is divided into, for example, ten, individual, smaller, lenses, 300. Each lens in this example is 1/10th of a square meter (100 square centimeters) and captures 100 watts of light energy. Therefore, a total of 1000 watts, or 1 KW, of light potential is being captured through one square meter of lensing—the same size lensing as in FIG. 2. Each of the ten lenses concentrates the light, for example, by a factor of 10. Thus the amount of PV 310 required to capture the concentrated light of each lens is 1/100th of a square meter, or 10 square centimeters. This PV is also 20% efficient in this example, so the 100 watts of potential light that is concentrated by each lens is converted into 20 watts of electricity.

If each of the PV were stationary, and aligned under each lens, the total power generated from all 10 lenses would be 200 watts (as per FIG. 1 and 2), or 20 watts per each piece of PV. In a stationary flat solar panel configuration, 1× sun mono-crystalline PV fails under the heat of 10× sunlight because of thermal conditions exceeding a maximum operating threshold (10× the light equals 10× the heat). Embodiments of the invention avoid this failure through dynamically spinning the PVs. When the PVs are rotated with precise timing, the build up of heat on the surface of the PVs is managed, that is, kept under an acceptable operating range. In one embodiment of the invention, when the PV 310 rotates between concentrating optics, and is not receiving concentrated light therefrom, during that break, the surface temperature of the PV returns to at or near ambient temperature depending on the thermal expansion characteristics of the PV.

Additionally, each PV stores energy captured from the previous lens(es) it passed beneath. How long the PV stores the energy is based on its decay rate. As it travels under subsequent lenses, again, some amount of the energy previously captured is still stored in the PV. As it rotates beneath the next lens, additional energy is captured and added to the energy that the PV was already storing, thereby increasing the total amount of energy captured by the PV.

With reference to FIG. 3, imagine looking at a single piece of PV 310 spinning beneath the focal points of the ten lenses 300 as described above. The energy output “staircases” up as illustrated in the graph at 320, so that some amount of light energy received at the PV from the first lens is added to some amount of light energy received from the next lens, and this happens each time the PV passes beneath a subsequent lens. The energy stored by the PV increases as the PV passes beneath each lens, up to a maximum threshold, depending on the type of PV, the excitation rate of the PV, the decay rate of the PV, the number of lenses, the concentrating capacity of each of the lenses, the spin rate of the PV, etc,

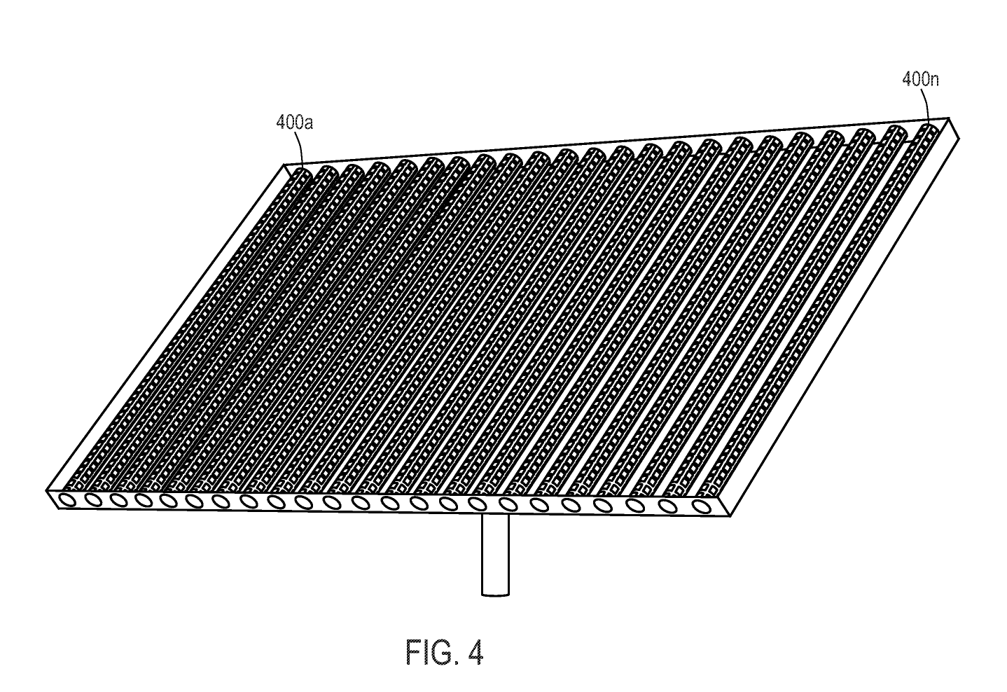

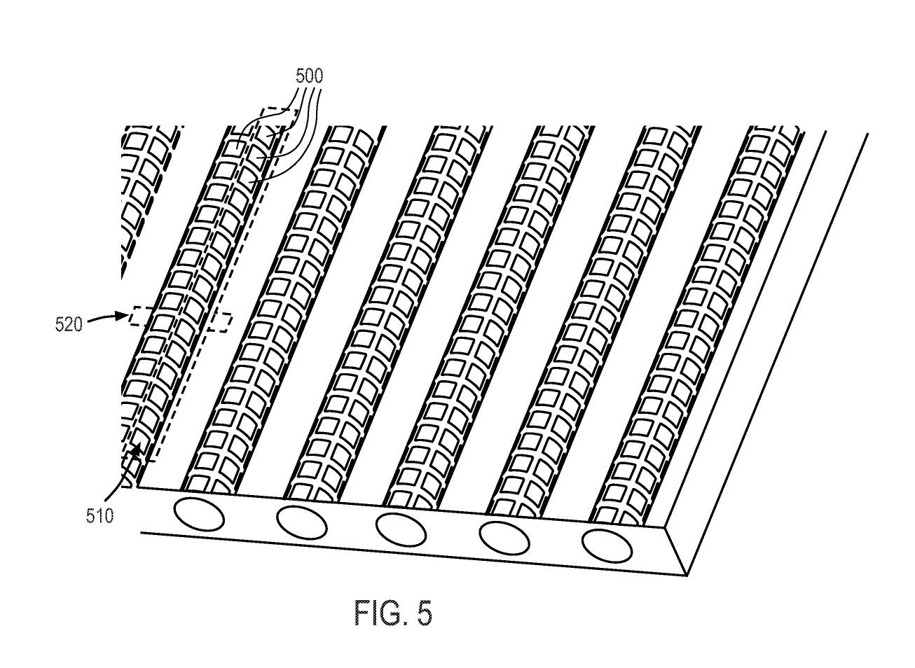

FIG. 4 illustrates an embodiment of the invention in which a rod or cylinder shaped substrate 400a is comprised of one or more PV cells (PVCs). Multiple such cylinders 400a-400n may be included in one embodiment, placed along side each other in substantially parallel configuration such as illustrated in FIG. 4. FIG. 5 provides a close-up view of the embodiment in FIG. 4 in which it can be seen multiple PVCs 500 are arranged in columns 510 along the length of a rod, and in rows 520 around a circumference of the rod. In one embodiment, the rods spin along their length. In simpler embodiments than illustrated in FIGS. 4 and 5, but nevertheless apparent from such Figs, a cylinder may comprise a single row of two or more PVCs, or a single column of two or more PVCs, or a combination of two or more rows and columns of PVCs, or a single PVC.

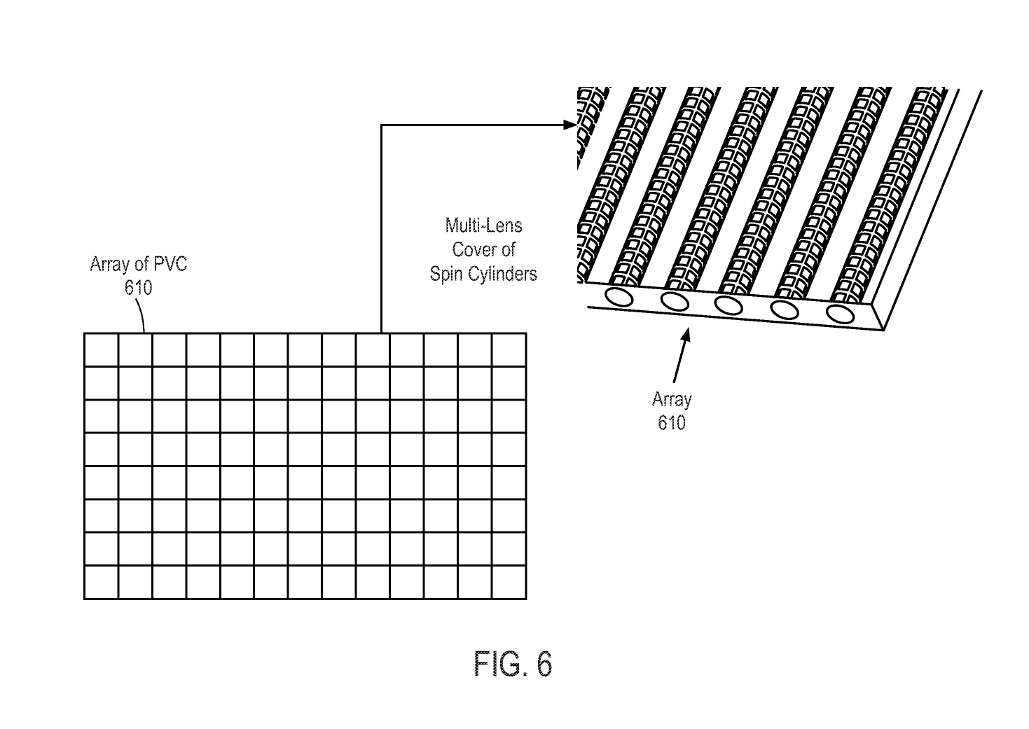

FIG. 6 illustrates a two-dimensional array of concentrating optics 600 that may be mounted above the array of cylinders or rods 610 illustrated in FIGS. 4 and 5. The two-dimensional array may comprise two or more lenses, shaped, sized, and arranged in such a way that a given PVC on a cylinder 610 only receives concentrated light from a single lens in the array, wherein the single lens is positioned directly above the PVC. Each rod-shaped substrate may rotate about its length, so that each of the PVCs in the rod spin near a lens respectively positioned directly above the PVC. In another embodiment, a PVC on a cylinder 610 may receive concentrated light from a plurality of lens positioned above or nearly above the PVC.

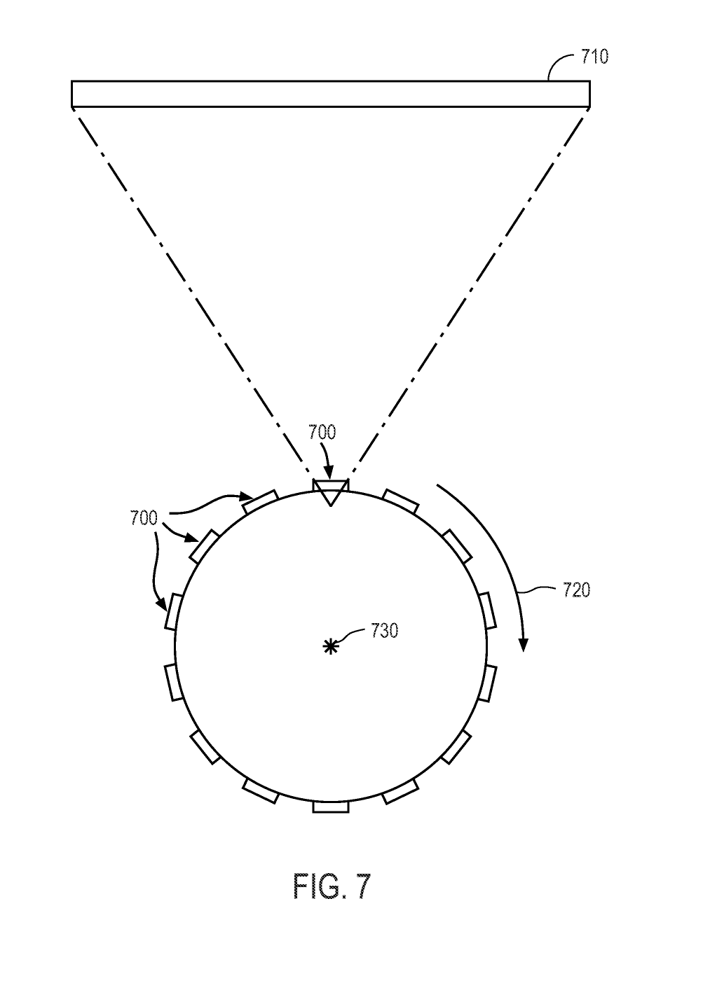

FIG. 7 illustrates a side view of an embodiment of the invention, in which one or more PVCs 700 arranged in a row around the circumference of a rod may be rotated by one of the lenses in the panel of lenses illustrated in FIG. 6. As each PVC 700 is positioned under a concentrating optic 710, light energy from a source, the sun, for example, concentrated by the lens, is directed onto the PVC as a target. By rotating the rod 720 on which the PVCs are located, the PVCs are cooled by air flowing passed the PVCs. In this manner, the PVCs can be kept at or below a maximum threshold operating temperature. In one embodiment the PVCs are rotated in a clockwise direction; in another, embodiment the rods are rotated in a counter-clockwise direction, around axis 730.

Furthermore, just as described above in the embodiment illustrated in FIG. 3, when a PVC passes or spins beneath the lenses at a sufficient rate, the energy output “staircases” up—so that some amount of light energy received at the PVC from the first time it is spun passed the lens is added to some amount of light energy received from the lens the second time the PVC is spun passed the lens, and this happens each time the PVC passes beneath the lens. The energy stored by the PVC increases as the PVC passes each time by the lens, up to a maximum threshold, depending on the type of PVC, the excitation rate of the PVC, the decay rate of the PVC, the concentrating capacity of the lens, the spin rate of the PVC, etc.

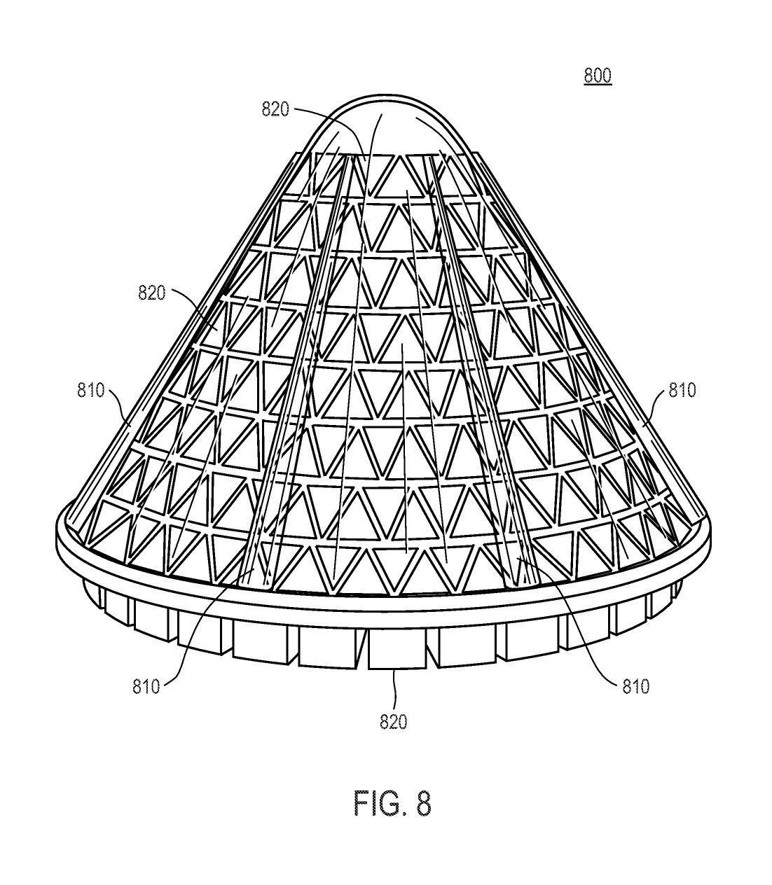

With reference to FIG. 8, in one embodiment of the invention, a light energy collection apparatus 800 comprises a plurality of concentrating optics 810, whether lenses or otherwise, each arranged substantially equidistant from a point of origin, for example, in a circle, to transfer light energy from a source of the light energy, such as the sun, to a target of the light energy, such as a PV cell 820. A substrate having a photovoltaic cell (PVC) deposited thereon operates as the target. The substrate is concentric to the plurality of concentrating optics, wherein the PVC is to collect the light energy to be transferred from each of the plurality of concentrating optics. In one embodiment, a central drive axle is coupled to the substrate and a motor is coupled to the central drive axle to rotate the central drive axle about a fixed axis to position, in turn, the substrate, and thereby the PVC, near each of the plurality of concentrating optics to collect the light energy to be transferred therefrom. For example, the central drive axle spins the PVC past each of the concentrating optics to collect the light energy to be transferred therefrom.

According to embodiments of the invention, the materials presently used for PV include monocrystalline silicon, polycrystalline silicon, amorphous silicon, cadmium telluride, and copper indium gallium selenide/sulfide.

It is appreciated that in various embodiments of the invention, the source of light energy may be any one of sunlight, lamplight, infrared light, or other electromagnetic radiation in or near the visible range of light. Furthermore, the location of the source of light energy may be a dynamic location (e.g., the sun as it passes overhead, in which case the location of the sun will vary by azimuth and/or altitude.)

While it is convenient to refer to the magnifying optics as lenses, it should be appreciated that embodiments of the invention are not limited to the use of magnifying lenses. Any type of concentrating optics may be used, including imaging-, non-imaging-, or anidolic optics, or a combination thereof.

In different embodiments of the invention, each of the plurality of concentrating optics is arranged substantially equidistant from a point of origin to simultaneously, irregularly, or periodically, transfer light energy from the source of the light energy to the target of the light energy. For example, a PV cell may concurrently receive sunlight, for some period of time, and at different angles of incidence, from nearby or adjacent concentrating optics. Alternatively, if the space between optics is significant, a PV cell, as it spins just past one of the optics but before it spins next to the next, or adjacent optic, may for a period of time receive no light energy from either of the optics. In one embodiment, the plurality of concentrating optics is fixedly arranged, for example, in the shape of one of a polygon, disc, cone, cylinder, or pyramid (that is, the outer surfaces of the plurality of concentrating optics are triangular and converge to a single point at a top of the pyramid, and a base of the pyramid may be trilateral, quadrilateral, or any polygon shape). In one embodiment, the outer surfaces or outer edges of the plurality of concentrating optics define a circumference, of a circle. In one embodiment, the center of the circle is at the point of origin.

According to various embodiments of the invention, the shape of the substrate is one of a polygon, disc, cone, cylinder, or pyramid (that is, the substrate's outer surfaces are triangular arid converge to a single point at the top, wherein the base of the pyramid can be trilateral, quadrilateral, or any polygon shape). In one embodiment, the outer surfaces or outer edges of the substrate defines a second circumference, c2, of a second circle, wherein a maximum circumference for the circumference c2 is less than the circumference c1, such that the PVC can collect light energy to be transferred from each of the plurality of concentrating optics.

In one embodiment, the substrate has further deposited thereon a plurality of additional PVCs 820, wherein each of the plurality of additional PVCs is a separate target, and wherein each of the plurality of additional PVCs is to collect the light energy to be transferred from each of the plurality of concentrating optics.

In one embodiment, the maximum circumference for the circumference c2 is less than the circumference c1, such that the PVC can optimally collect light energy to be transferred from each of the plurality of concentrating optics. Additionally, the surface area of each of the plurality of concentrating optics may vary for one or more of the plurality of concentrating optics, and may be greater than, equal to, or less than, the surface area of the PVC.

In various embodiments, the edge of the PVC and the edge of each of the plurality of concentrating optics is a convex polygon, wherein a convex polygon is defined as any line drawn through the polygon meets its boundary exactly twice; equivalently, all its interior angles are less than 180 degrees. In one embodiment, the convex polygon is cyclic that is, all corners lie on a single circle), equilateral (that is, all edges are of the same length), or regular (that is, both cyclic and equilateral).

In one embodiment, the drive axle spins, in turn, the PVC near each of the plurality of concentrating optics at a rate sufficient to add an additional amount of electrical energy stored by the PVC from light energy received from a most recent near one of the plurality of concentrating optics to a first amount of electrical energy stored by the PVC from light energy received from a previously near one of the plurality of concentrating optics. Importantly, the embodiment positions, in turn, the PVC near each of the plurality of concentrating optics at a rate sufficient to avoid exceeding a maximum threshold surface temperature for the PVC. In this way, the embodiment spins the PVC past each of the plurality of concentrating optics at a rate sufficient to reduce a surface temperature of the PVC. This reduction in temperature is primarily due to airflow over the PVC as it is spun by the drive axle.

It should be appreciated that an embodiment of the invention can further include a base rotatably coupled to the central drive axle, a battery to store electrical power generated by the PVC, a charge controller coupled to the PVC and battery to feed direct current electricity from the PVC to the battery, and a power inverter coupled to the battery to convert direct current electricity output by the battery to alternating current electricity for input to an electrical appliance.

In another embodiment of the invention with reference to FIGS. 4-7, a light energy collection apparatus comprises one or more concentrating optics fixed in a plane to transfer light energy from a source of the light energy to a target of the light energy. A substrate having a photovoltaic cell (PVC) deposited thereon operates as the target. The substrate is proximate to the concentrating optic, such that the PVC can collect the light energy to be transferred from the concentrating optic. A central drive axle is coupled to the substrate, and a motor is coupled to the central drive axle to rotate the central drive axle about a fixed axis to position the substrate, and thereby the PVC, near the concentrating optic to collect the light energy to be transferred therefrom. In one embodiment, the motor rotates the PVC at a rate sufficient to at least maintain a surface temperature of the PVC through airflow. For example, the PVC spins at a rate that does not exceed a maximum operating temperature for the PVC.

As mentioned above in other embodiments, in this embodiment, the light energy may be sunlight, lamplight, infrared light, or other electromagnetic radiation in or near the visible range of light. Further, the concentrating optic comprises an imaging-, non-imaging-, or anidolic optic mounted in a plane. In one embodiment, the plane is parallel to a plane of one or more rotating cylindrical shaped substrates. In other embodiments, the shape of the substrate is one of a polygon, disc, cone, or pyramid. In any case, the substrate is proximate to the concentrating optic such that the PVC can optimally collect light energy to be transferred from the concentrating optic.

In various embodiments, the area of a surface of the concentrating optic may be greater than, equal to, or less than, an area of a surface of the PVC. In one embodiment, the PVC, and the concentrating optic, is a convex polygon.

In one embodiment, the central drive axle, as driven by the motor, repeatedly positions the PVC near the concentrating optic at a rate sufficient to add an additional amount of electrical energy stored by the PVC from light energy received from the concentrating optic to a first amount of electrical energy stored by the PVC from light energy received from the concentrating optic.

The embodiments illustrated in FIGS. 4-7 may further include a base panel, or tray, rotatably coupled to the central drive axle, a battery to store electrical power generated by the PVC, a charge controller coupled to the PVC and battery to feed direct current electricity from the PVC to the battery, and a power inverter coupled to the battery to convert direct current electricity output by the battery to alternating current electricity for input to an electrical appliance.

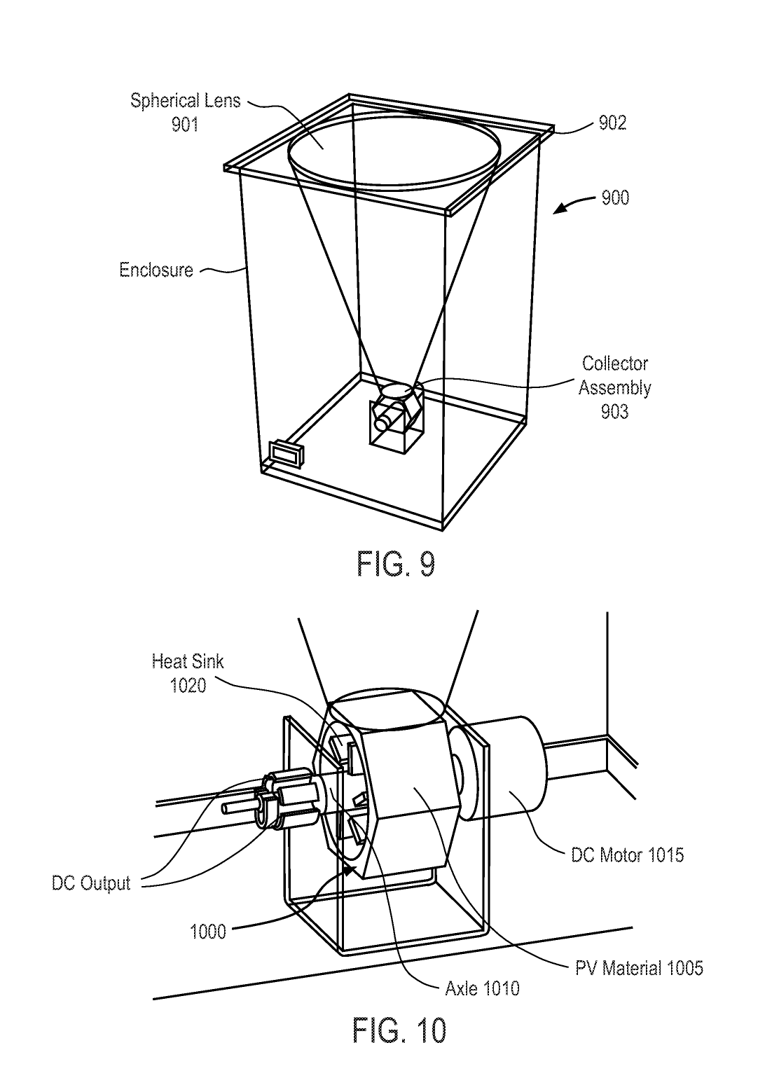

With reference to FIGS. 9 and 10, another embodiment of the invention is described. A light energy collection apparatus 900 comprises one or more concentrating optics 901. fixed in a plane 902 to transfer light energy from a source of the light energy, such as the sun, to a target of the light energy. A collector assembly 903 comprises a substrate 1000 having a photovoltaic cell (PVC) 1005 deposited thereon that operates as the target. The substrate 1000 is proximate to the concentrating optic 901, such that the PVC 1005 can collect the light energy to be transferred from the concentrating optic 901. A central drive axle 1010 is coupled to the substrate, and a motor 1015 is coupled to the central drive axle to rotate the central drive axle about a fixed axis to position the substrate, and thereby the PVC, near the concentrating optic to collect the light energy to be transferred therefrom. In one embodiment, the motor rotates the PVC at a rate sufficient to at least maintain a surface temperature of the PVC. For example, the PVC spins at a rate that does not exceed a maximum operating temperature for the PVC. Air flow over the PVC as it spins helps maintain or even reduce the operating temperature of the PVC. Additionally, heat sink 1020 further helps maintain or reduce the operating temperature of the PVC.

As mentioned above in other embodiments, in this embodiment, the light energy may be sunlight, lamplight, infrared light, or other electromagnetic radiation in or near the visible range of light. Further, the concentrating optic comprises an imaging-, non-imaging-, or anidolic optic mounted in a plane. In one embodiment, the plane is parallel at times to a plane of one of the surfaces of the rotating hexagonal shaped substrate. The substrate is set an appropriate distance from the concentrating optic such that the PVC can optimally collect light energy to be transferred from the concentrating optic.

In this embodiment, the area of a surface of the concentrating optic is greater than an area of one of the six surfaces of the PVC. The drive axle rotates under power from the motor to repeatedly position each of the six surfaces of the PVC near the concentrating optic at a rate sufficient to add an additional amount of electrical energy stored by the PVC from light energy received from the concentrating optic to a first amount of electrical energy stored by the PVC from light energy received from the concentrating optic.

1. A light energy collection apparatus, comprising:
a plurality of concentrating optics each arranged substantially equidistant from a point of origin to transfer light energy from a source of the light energy to a target of the light energy;
a substrate having a photovoltaic cell (PVC) deposited thereon as the target, the substrate concentric to the plurality of concentrating optics, wherein the PVC to collect the light energy to be transferred from each of the plurality of concentrating optics;
a central drive axle coupled to the substrate; and
a motor coupled to the central drive axle to rotate the central drive axle about a fixed axis to position, in turn, the substrate, and thereby the PVC, near each of the plurality of concentrating optics to collect the light energy to be transferred therefrom.

2. The apparatus of claim 1, wherein the light energy is one of sunlight, lamplight, infrared light, or other electromagnetic radiation in or near the visible range of light.

3. The apparatus of claim 1, wherein the plurality of concentrating optics comprises a plurality of, imaging-, non-imaging-, or anidolic optics.

4. The apparatus of claim 1, wherein the plurality of concentrating optics is each arranged substantially equidistant from a point of origin to either simultaneously, irregularly, or periodically, transfer light energy from the source of the light energy to the target of the light energy.

5. The apparatus of claim 1, wherein the plurality of concentrating optics is fixedly arranged.

6. The apparatus of claim 5, wherein the plurality of concentrating optics is fixedly arranged in a shape of one of a polygon, disc, cone, cylinder, or pyramid.

7. The apparatus of claim 6, wherein outer surfaces or outer edges of the plurality of concentrating optics define a circumference, c1, of a circle, and wherein a center of the circle is at the point of origin.

8. The apparatus of claim 7, wherein a shape of the substrate is one of a polygon, disc, cone, cylinder, or pyramid.

9. The apparatus of claim 8, wherein outer surfaces or outer edges of the substrate defines a second circumference, c2, of a second circle, wherein a maximum circumference for the circumference c2 is less than the circumference c1, such that the PVC can collect light energy to be transferred from each of the plurality of concentrating optics.

10. The apparatus of claim 9, wherein the maximum circumference for the circumference c2 is less than the circumference c1, such that the PVC can optimally collect light energy to be transferred from each of the plurality of concentrating optics.

11. The apparatus of claim 1, wherein an area of a surface of each of the plurality of concentrating optics may vary for one or more of the plurality of concentrating optics, and may be greater than, equal to, or less than, an area of a surface of the PVC.

12. The apparatus of claim 1, wherein the PVC and each of the plurality of concentrating optics is a convex polygon.

13. The apparatus of claim 12, wherein the convex polygon is cyclic, equilateral, or regular.

14. The apparatus of claim 1, wherein the motor positions, in turn, the PVC near each of the plurality of concentrating optics at a rate sufficient to add an additional amount of electrical energy stored by the PVC from light energy received from a most recent near one of the plurality of concentrating optics to a first amount of electrical energy stored by the PVC from light energy received from a previously near one of the plurality of concentrating optics.

15. The apparatus in claim 1, wherein the motor positions, in turn, the PVC near each of the plurality of concentrating optics at a rate sufficient to avoid exceeding a maximum threshold surface temperature for the PVC.

16. The apparatus of claim 1, wherein the motor spins the PVC past each of the plurality of concentrating optics at a rate sufficient to reduce a surface temperature of the PVC.

17. The apparatus of claim 1, further comprising:
a base rotatably coupled to the central drive axle;
a battery to store electrical power generated by the PVC;
a charge controller coupled to the PVC and battery to fee direct current electricity from the PVC to the battery; and
a power inverter coupled to the battery to convert direct current electricity output by the battery to alternating current electricity for input to an electrical appliance.

18. The apparatus of claim 1, wherein the substrate has further deposited thereon a plurality of additional PVCs, wherein each of the plurality of additional PVCs is a separate target, and wherein each of the plurality of additional PVCs is to collect the light energy to be transferred from each of the plurality of concentrating optics.

19. The apparatus of claim 1, wherein a location of the source of light energy is one of a dynamic location or a static location.

20. The apparatus of claim 15, wherein the dynamic location of the source of light energy may vary in one of azimuth, altitude, or both azimuth and altitude.

21. A light energy collection apparatus, comprising:
a concentrating optic to transfer light energy from a source of the light energy to a target of the light energy;
a substrate having a photovoltaic cell (PVC) deposited thereon as the target, the substrate proximate to the concentrating optic, wherein the PVC to collect the light energy to be transferred from the concentrating optic;
a central drive axle coupled to the substrate; and
a motor coupled to the central drive axle to rotate the central drive axle about a fixed axis to position, in turn, the substrate, and thereby the PVC, near the concentrating optic to collect the light energy to be transferred therefrom, wherein the motor rotates the PVC at a rate sufficient to at least maintain a surface temperature of the PVC.

22. The apparatus of claim 21, wherein the light energy is one of sunlight, lamplight, infrared light, or other electromagnetic radiation in or near the visible range of light.

23. The apparatus of claim 21, wherein the concentrating optic comprises an imaging-, non-imaging-, or anidolic optic.

24. The apparatus of claim 21, wherein the concentrating optic is fixedly arranged.

25. The apparatus of claim 21, wherein a shape of the substrate is one of a polygon, disc, cone, cylinder, or pyramid.

26. The apparatus of claim 21, wherein the substrate is proximate to the concentrating optic such that the PVC can optimally collect light energy to be transferred from the concentrating optic.

27. The apparatus of claim 21, wherein an area of a surface of the concentrating optic may be greater than, equal to, or less than, an area of a surface of the PVC.

28. The apparatus of claim 21, wherein the PVC, and the concentrating optic, is a convex polygon.

29. The apparatus of claim 21, wherein the motor repeatedly positions the PVC near the concentrating optic at a rate sufficient to add an additional amount of electrical energy stored by the PVC from light energy received from the concentrating optic to a first amount of electrical energy stored by the PVC from light energy received from the concentrating optic.

30. The apparatus of claim 21, further comprising:
a base rotatably coupled to the central drive axle;
a battery to store electrical power generated by the PVC;
a charge controller coupled to the PVC and battery to feed direct current electricity from the PVC to the battery; and
a power inverter coupled to the battery to convert direct current electricity output by the battery to alternating current electricity for input to an electrical appliance.

31. The apparatus of claim 21, wherein the substrate has further deposited thereon a plurality of additional PVCs, wherein each of the plurality of additional PVCs is a separate target, and wherein each of the plurality of additional PVCs is to collect the light energy to be transferred from the concentrating optic.
